(19) United States
(12) Patent Application Publication
(10) Pub. No.: US 2017/0230034 A1
(43) Pub. Date: Aug. 10, 2017

(54) COMPARATOR CIRCUITS

(71) Applicant: MediaTek Inc., Hsin-Chu (TW)

(72) Inventors: Yen-Hsin WEI, Kaohsiung City (TW); Wen-Hua CHANG, Tainan City (TW)

(21) Appl. No.: 15/141,785

(22) Filed: Apr. 28, 2016

Related U.S. Application Data
(60) Provisional application No. 62/291,026, filed on Feb. 4, 2016.

(51) Int. Cl. H03K 5/007; H03K 5/24

(52) U.S. Cl. CPC H03K 5/007; H03K 5/2472

(57) ABSTRACT

A comparator circuit having an offset voltage includes a first input circuit, a second input circuit and a control circuit. The first input circuit includes a first input terminal receiving a first input signal. The second input circuit includes a second input terminal receiving a second input signal. The control circuit is coupled to a first intermediate terminal and a second intermediate terminal and resets a voltage at the first intermediate terminal and a voltage at the second intermediate terminal according to an offset cancellation voltage. The first intermediate terminal is coupled between the first input terminal and a first output terminal of the comparator circuit, the second intermediate terminal is coupled between the second input terminal and a second output terminal of the comparator circuit, and the first intermediate terminal and the second intermediate terminal are symmetric terminals in the comparator circuit.

### CROSS REFERENCE TO RELATED APPLICATIONS

This application claims the benefit of U.S. Provisional Application No. 62/291,026 filed 2016 Feb. 4 entitled “Comparator Calibration,” the entire contents of which are hereby incorporated by reference.

### BACKGROUND OF THE INVENTION

Field of the Invention

The invention relates to a comparator circuit, and more particularly to a comparator circuit with a control circuit to calibrate the comparator circuit so as to compensate for the offset voltage of the comparator circuit.

Description of the Related Art

A comparator is used to compare two signals at its input terminals and to selectively control its output to indicate which of the two input signals is greater. As comparators are not ideal circuit elements, every comparator will have an offset voltage.

The offset voltage is usually caused by process variation and may be on the order of a few millivolts, but the presence of the offset of the comparator may distort the output of the device.

To compensate for the offset voltage, a novel control circuit and controlling methods thereof to calibrate a comparator circuit is required.

### BRIEF SUMMARY OF THE INVENTION

Comparator circuits are provided. An exemplary embodiment of a comparator circuit having an offset voltage comprises a first input circuit, a second input circuit and a control circuit. The first input circuit comprises a first input terminal receiving a first input signal. The second input circuit comprises a second input terminal receiving a second input signal. The control circuit is coupled to a first intermediate terminal and a second intermediate terminal and resets a voltage at the first intermediate terminal and a voltage at the second intermediate terminal according to an offset cancellation voltage. The first intermediate terminal is coupled between the first input terminal and a first output terminal of the comparator circuit, the second intermediate terminal is coupled between the second input terminal and a second output terminal of the comparator circuit, and the first intermediate terminal and the second intermediate terminal are symmetric terminals in the comparator circuit.

An exemplary embodiment of a comparator circuit having an offset voltage comprises a first circuit, a second circuit and a control circuit. The first circuit comprises a first input terminal receiving a first input signal and a first output terminal. The second circuit comprises a second input terminal receiving a second input signal and a second output terminal. The first circuit and the second circuit are symmetric in structure. The control circuit is coupled to a first intermediate terminal and a second intermediate terminal and resets a voltage at the first intermediate terminal and a voltage at the second intermediate terminal according to an offset cancellation voltage. The first intermediate terminal is located on a path from the first input terminal to the first output terminal. The second intermediate terminal is located on a path from the second input terminal to the second output terminal. The first intermediate terminal and the second intermediate terminal are symmetric terminals in the comparator circuit.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 is a block diagram of a comparator circuit according to an embodiment of the invention;

FIG. 2 is a block diagram of a comparator circuit according to another embodiment of the invention;

FIG. 3A is an exemplary circuit diagram of a comparator circuit according to an embodiment of the invention;

FIG. 3B is another exemplary circuit diagram of a comparator circuit according to another embodiment of the invention;

FIG. 4A is an exemplary circuit diagram of a comparator circuit according to an embodiment of the invention;

FIG. 4B is another exemplary circuit diagram of a comparator circuit according to another embodiment of the invention;

FIG. 5A is an exemplary circuit diagram of a comparator circuit according to an embodiment of the invention;

FIG. 5B is another exemplary circuit diagram of a comparator circuit according to another embodiment of the invention;

FIG. 6A is an exemplary circuit diagram of a comparator circuit according to an embodiment of the invention;

FIG. 6B is another exemplary circuit diagram of a comparator circuit according to another embodiment of the invention;

FIG. 7A is an exemplary circuit diagram of a comparator circuit according to an embodiment of the invention;

FIG. 7B is another exemplary circuit diagram of a comparator circuit according to another embodiment of the invention;

FIG. 8A is an exemplary circuit diagram of a comparator circuit according to an embodiment of the invention; and

FIG. 8B is another exemplary circuit diagram of a comparator circuit according to another embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

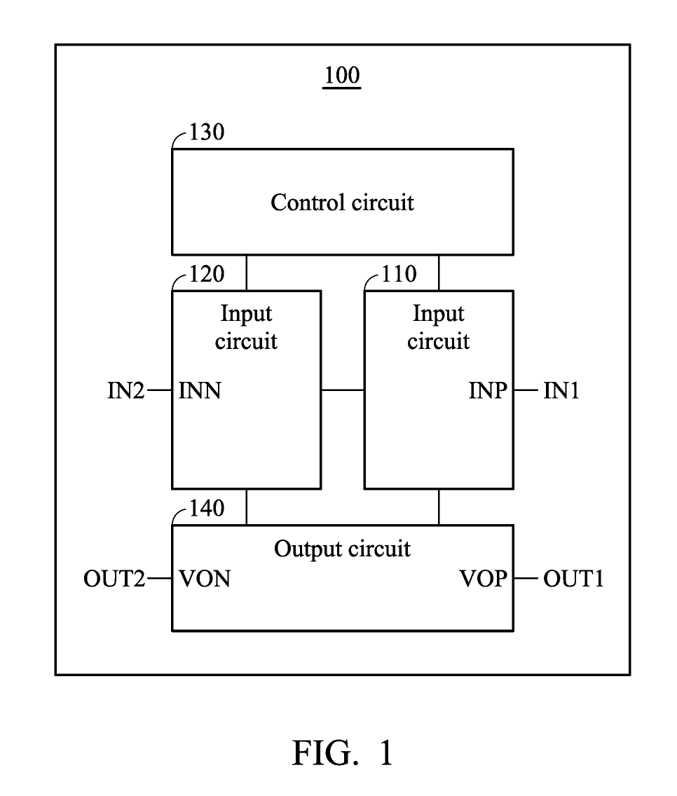

FIG. 1 is a block diagram of a comparator circuit according to an embodiment of the invention. The comparator circuit 100 compares two input signals and outputs a comparison result to indicate which of the two input signals is greater. According to an embodiment of the invention, the comparator circuit 100 may comprise input circuits 110 and 120, a control circuit 130 and an output circuit 140. The input circuit 110 comprises an input terminal INP receiving an input signal IN1. The input circuit 120 comprises an input terminal INN receiving an input signal IN2. The output circuit 140 comprises output terminals VOP and VON for outputting the comparison result (indicated by the output signals OUT1 and OUT2).

According to an embodiment of the invention, the control circuit 130 is coupled to two or more intermediate terminals of the comparator circuit 100 and resets a voltage at the intermediate terminals according to an offset cancellation voltage Vcancel. For example, the control circuit 130 is coupled to two intermediate terminals. The first intermediate terminal is coupled between the input terminal INN and one of the output terminals VON and VOP, the second intermediate terminal is coupled between the input terminal INN and another one of the output terminals VON and VOP. Therefore, in the embodiments of the invention, the first intermediate terminal is located on a path (for example, an electronic path, such as a voltage path or a current path in which a current flowing through) between the input terminal INN and the output terminal VON/VOP, and second intermediate terminal is located on a path (for example, an electronic path, such as a voltage path or a current path in which a current flowing through) between the input terminal INP and the output terminal VOP/VON.

Note that in the embodiments of the invention, each two of the two or more intermediate terminals which are reset to some voltages in the reset phase should be symmetric terminals in the comparator circuit 100. For example, the first intermediate terminal and the second intermediate terminal as illustrated above are symmetric terminals in the comparator circuit 100. When the comparator circuit 100 has none-zero offset voltage, voltages at the two or more intermediate terminals, in the reset phase, are reset to different voltage levels according to the offset cancellation voltage Vcancel, so as to compensate for the offset voltage.

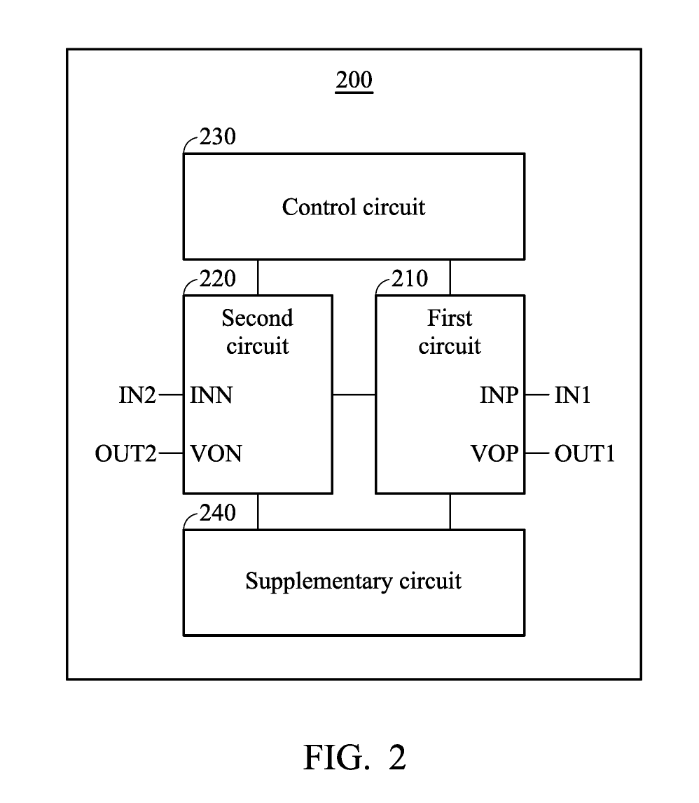

FIG. 2 is a block diagram of a comparator circuit according to another embodiment of the invention. The comparator circuit 200 compares two input signals and outputs a comparison result to indicate which of the two input signals is greater. According to an embodiment of the invention, the comparator circuit 200 may comprise a first circuit 210, a second circuit 220 and a control circuit 230. The first circuit 210 comprises an input terminal INP receiving an input signal IN1 and an output terminal VOP. The second circuit 220 comprises an input terminal INN receiving an input signal IN2 and an output terminal VON. The first circuit 210 and the second circuit 220 are symmetric in structure. For example, the first circuit 210 and the second circuit 220 may be mirror-symmetric circuits or may have mirror-symmetric structures. That is, the structure of the first circuit 210 and the structure of the second circuit 220 are mirror-symmetrical with each other.

According to an embodiment of the invention, the comparator circuit 200 may further comprise a supplementary circuit 240 coupled to the first circuit 210 and the second circuit 220. The supplementary circuit 240 may comprise the remaining element(s), which may not have symmetric structure with other circuit, of the comparator circuit 200.

According to an embodiment of the invention, the control circuit 230 is coupled to two or more intermediate terminals of the comparator circuit 200 and resets a voltage at the intermediate terminals according to an offset cancellation voltage Vcancel. For example, the control circuit 230 is coupled to two intermediate terminals. The first intermediate terminal is coupled between the input terminal INN and one of the output terminals VON and VOP, the second intermediate terminal is coupled between the input terminal INN and another one of the output terminals VON and VOP. Therefore, in the embodiments of the invention, the first intermediate terminal is located on a path (for example, an electronic path, such as a voltage path or a current path in which a current flowing through) between the input terminal INN and the output terminal VON/VOP, and second intermediate terminal is located on a path (for example, an electronic path, such as a voltage path or a current path in which a current flowing through) between the input terminal INP and the output terminal VOP/VON.

Note that in the embodiments of the invention, each two of the two or more intermediate terminals for performing the reset operation should be symmetric terminals in the comparator circuit 200. For example, the first intermediate terminal and the second intermediate terminal as illustrated above are symmetric terminals in the comparator circuit 200. When the comparator circuit 200 has none-zero offset voltage, voltages at the two or more intermediate terminal, in the reset phase, are reset to different voltage levels according to the offset cancellation voltage Vcancel, so as to compensate for the offset voltage.

According to an embodiment of the invention, the control circuit 130/230 resets the voltages at the intermediate terminals in a reset state of the comparator circuit 100/200. After the reset is done, the comparator circuit 100/200 may work in a normal state to compare two input signals and output a comparison result to indicate which of the two input signals is greater.

The concepts of how to reset the voltages at the intermediate terminals to compensate for the offset voltage are illustrated in the following paragraphs.

According to an embodiment of the invention, when the input circuit 110 or the first circuit 210 has a driving capability stronger than that of the input circuit 120 or the second circuit 220, the control circuit 130 or 230 provides a reset voltage which is lower than a supply voltage VDD to the second intermediate terminal coupled to or located inside of the input circuit 120 or the second circuit 220 when the voltage at the first intermediate terminal coupled to or located inside of the input circuit 110 or the first circuit 210 is reset to the supply voltage VDD.

According to another embodiment of the invention, when the input circuit 110 or the first circuit 210 has a driving capability stronger than that of the input circuit 120 or the second circuit 220, the control circuit 130 or 230 provides a reset voltage which is greater than a ground voltage to the second intermediate terminal coupled to or located inside of the input circuit 120 or the second circuit 220 when the voltage at the first intermediate terminal coupled to or located inside of the input circuit 110 or the first circuit 210 is reset to the ground voltage Vss.

According to an embodiment of the invention, the control circuit 130/230 may provide a first reset voltage to the first intermediate terminal and provide a second reset voltage to the second intermediate terminal, and the difference between the first reset voltage and the second reset voltage may be set to the offset cancellation voltage Vcancel.

According to an embodiment of the invention, the offset cancellation voltage Vcancel is positively related to the absolute value of the offset voltage. For example, the offset cancellation voltage Vcancel increases as the absolute value of the offset voltage of the comparator increases.

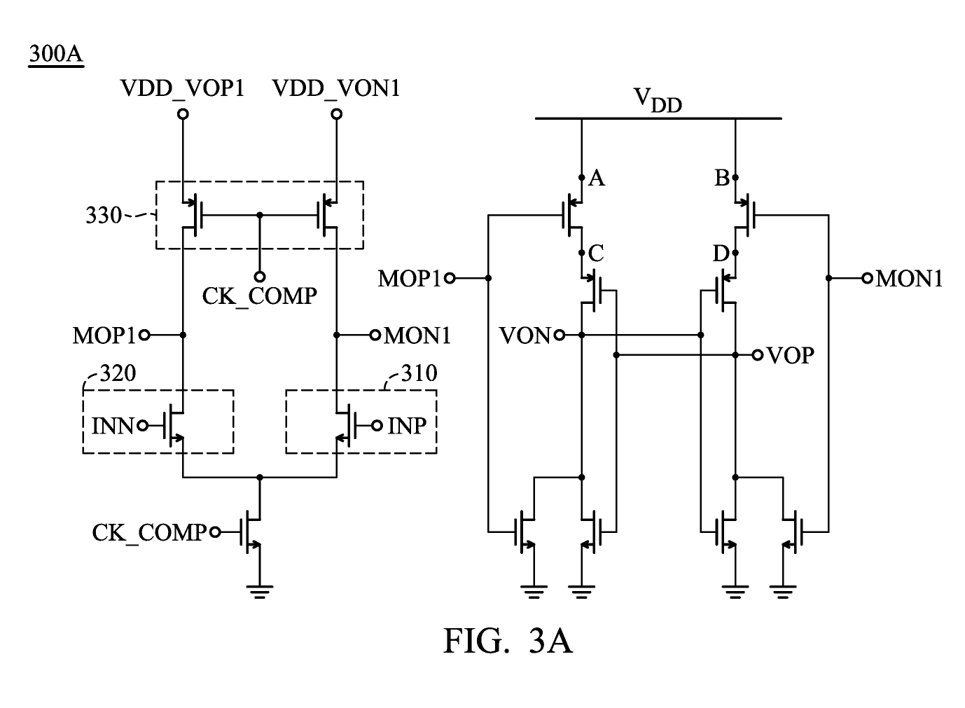

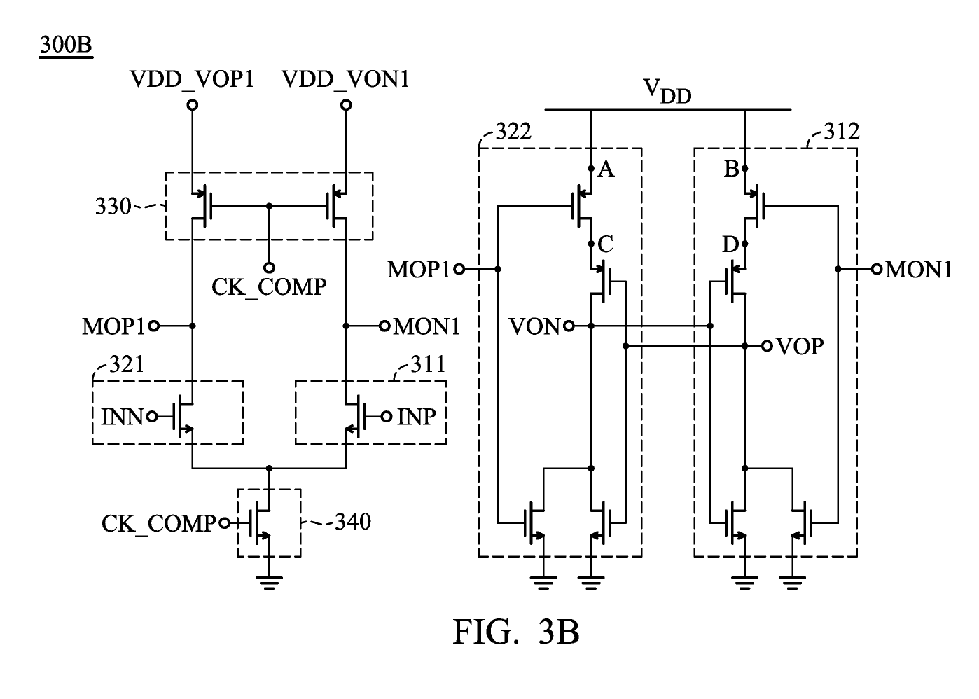

FIG. 3A is an exemplary circuit diagram of a comparator circuit according to an embodiment of the invention. The comparator circuit 300A is a two-stage comparator and may comprise input circuits 310 and 320, a control circuit 330, and an output circuit (comprising the remaining circuit elements of the comparator circuit 300A).

FIG. 3B is another exemplary circuit diagram of a comparator circuit according to another embodiment of the invention. The comparator circuit 300B is a two-stage comparator and may comprise a first circuit comprising the circuit subunits 311 and 312, a second circuit comprising the circuit subunits 321 and 322, a control circuit 330 and a supplementary circuit 340. The first circuit and the second circuit have symmetric structure. That is, the structure of the first circuit and the structure of the second circuit are symmetrical with each other.

FIG. 3A and FIG. 3B show basically the same circuit. Therefore, it should be understood that in the embodiments, the components of the first circuit, the second circuit and the input circuits of a comparator circuit may be flexibly designed. The comparator circuits 300A and 300B may be reset based on the same manner. Therefore, discussion of the reset operation of the comparator circuit 300B will be omitted for brevity.

According to an embodiment of the invention, the comparator circuit 300A may receive a reset control signal CK_COMP and perform the reset operation in the reset state in response to the reset control signal CK_COMP.

The intermediate terminals to be reset may be flexibly selected. For example, the intermediate terminals may be the terminals MOP1 and MON1. For another example, the intermediate terminals may also be, or may further comprise, terminals A and B. In yet another example, the intermediate terminals may also be, or may further comprise, terminals C and D.

Taking the intermediate terminals MOP1 and MON1 as an example, when the reset control signal CK_COMP goes low, the comparator circuit 300A works in the reset state and the reset voltages VDD_VOP1 and VDD_VON1 are respectively provided to the intermediate terminals MOP1 and MON1.

When the offset voltage of the comparator circuit 300A is not zero, the reset voltages VDD_VOP1 and VDD_VON1 may be pre-set to different voltage levels.

For example, when the input circuit 310 (or, the first circuit of the comparator circuit 300B) has a driving capability stronger than that of the input circuit 320 (or, the second circuit of the comparator circuit 300B), the reset voltage VDD_VOP1 may be set to a value lower than the reset voltage VDD_VON1.

To be more specific, the reset voltage VDD_VOP1 may be set to (VDD−Vcancel) when the reset voltage VDD_VON1 is set to VDD. As discussed above, the offset cancellation voltage Vcancel is positively related to the absolute value of the offset voltage.

Note that when the intermediate terminals are selected as the terminals A and B, the terminals C and D, or the terminals A, B, C and D, the supply voltage VDD coupled to the terminals A and B or C and D, may be replaced by different reset voltages based on the concept as described above.

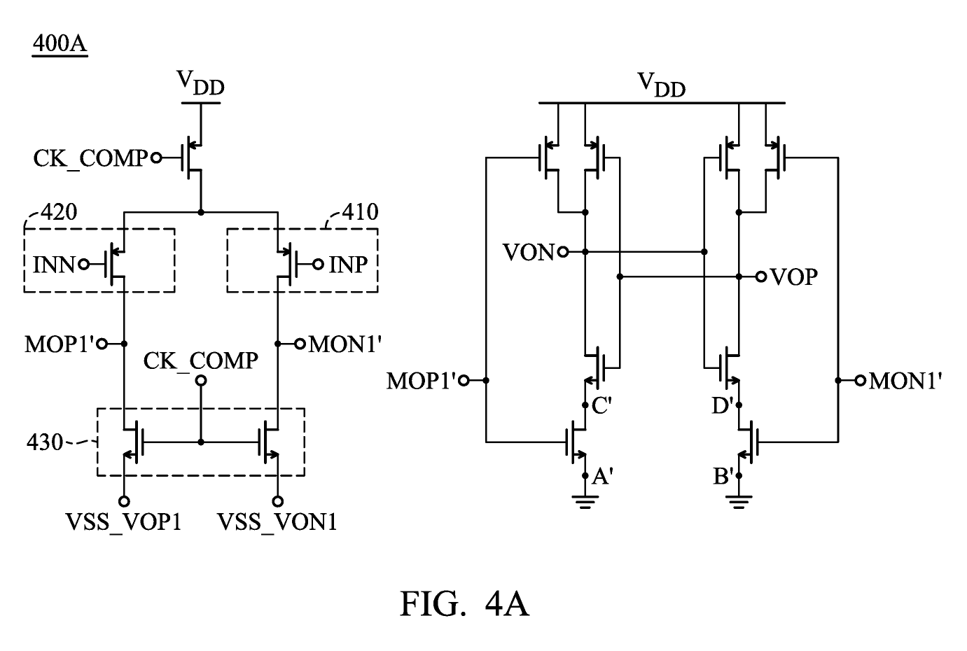

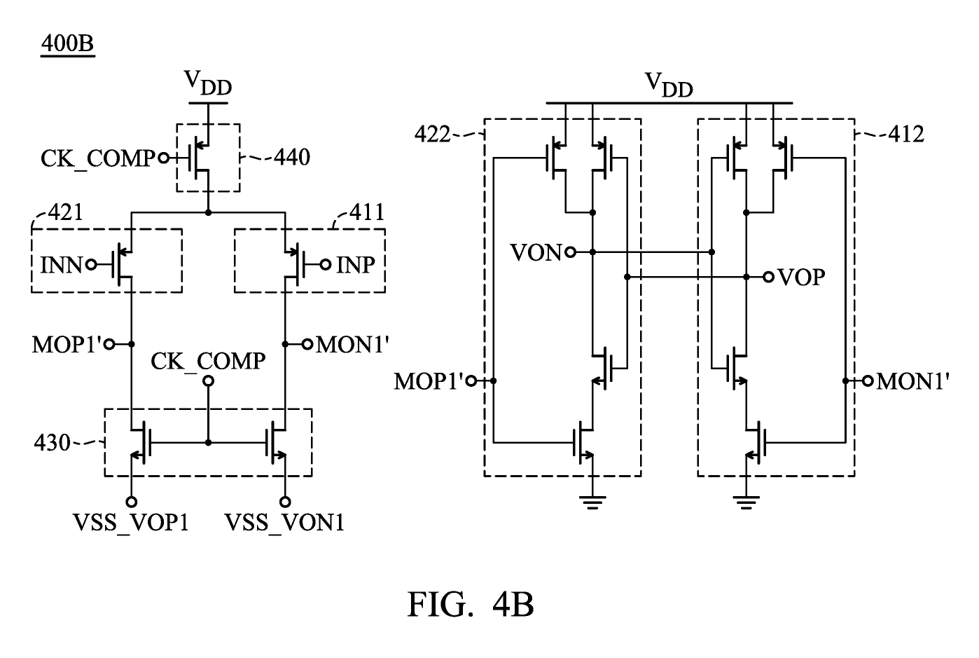

FIG. 4A is an exemplary circuit diagram of a comparator circuit according to an embodiment of the invention. The comparator circuit 400A is a two-stage comparator and may comprise input circuits 410 and 420, a control circuit 430 and an output circuit (comprising the remaining circuit elements of the comparator circuit 400A).

FIG. 4B is another exemplary circuit diagram of a comparator circuit according to another embodiment of the invention. The comparator circuit 400B is a two-stage comparator and may comprise a first circuit comprising the circuit subunits 411 and 412, a second circuit comprising the circuit subunits 421 and 422, a control circuit 430 and a supplementary circuit 440. The first circuit and the second circuit have symmetric structure. That is, the structure of the first circuit and the structure of the second circuit are symmetrical with each other.

FIG. 4A and FIG. 4B show basically the same circuit. Therefore, it should be understood that in the embodiments, the components of the first circuit, the second circuit and the input circuits of a comparator circuit may be flexibly designed. The comparator circuits 400A and 400B may be reset based on the same manner. Therefore, discussion of the reset operation of the comparator circuit 400B will be omitted for brevity.

According to an embodiment of the invention, the comparator circuit 400A may receive a reset control signal CK_COMP and perform the reset operation in the reset state in response to the reset control signal CK_COMP.

The intermediate terminals to be reset may be flexibly selected. For example, the intermediate terminals may be the terminals MOP1′ and MON1′. For another example, the intermediate terminals may also be, or may further comprise, terminals A′ and B′. In yet another example, the intermediate terminals may also be, or may further comprise, terminals C′ and D′.

Taking the intermediate terminals MOP1′ and MON1′ as an example, when the reset control signal CK_COMP goes high, the comparator circuit 400A works in the reset state and the reset voltages VSS_VOP1 and VSS₁₃ VON1 are respectively provided to the intermediate terminals MOP1′ and MON1′.

When the offset voltage of the comparator circuit 400A is not zero, the reset voltages VSS_VOP1 and VSS_VON1 may be pre-set to different voltage levels.

For example, when the input circuit 410 (or, the first circuit of the comparator circuit 400B) has a driving capability stronger than that of the input circuit 420 (or, the second circuit of the comparator circuit 400B), the reset voltage VSS_VOP1 may be set to a value greater than the reset voltage VSS_VON1.

To be more specific, the reset voltage VSS_VOP1 may be set to (VSS+Vcancel) when the reset voltage VSS_VON1 is set to VSS. As discussed above, the offset cancellation voltage Vcancel is positively related to the absolute value of the offset voltage.

Note that when the intermediate terminals are selected as the terminals A′ and B′, the terminals C′ and D′, or the terminals A′, B′, C′ and D′, the ground voltage VSS coupled to the terminals A′ and B′ or C′ and D′may be replaced by different reset voltages based on the concept as described above.

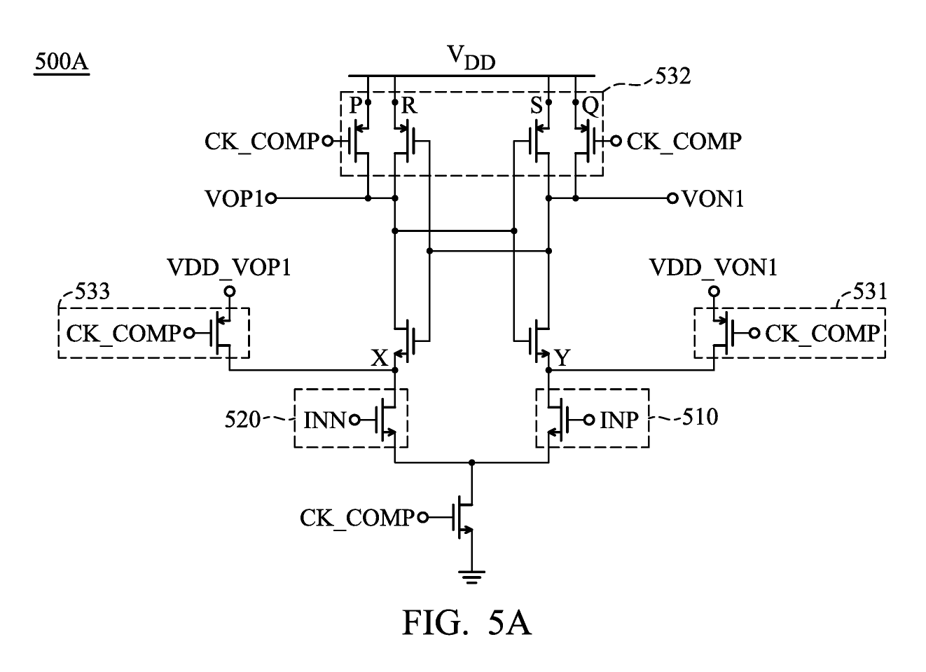

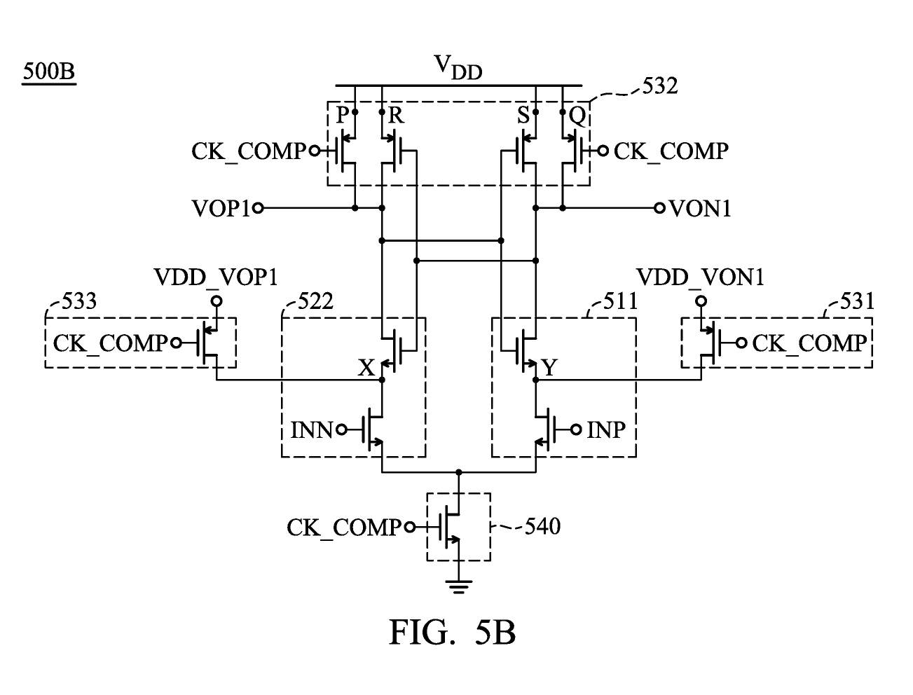

FIG. 5A is an exemplary circuit diagram of a comparator circuit according to an embodiment of the invention. The comparator circuit 500A is a one-stage comparator and may comprise input circuits 510 and 520, a control circuit comprising circuit subunits 531, 532 and 533 and an output circuit (comprising the remaining circuit elements of the comparator circuit 500A).

FIG. 5B is another exemplary circuit diagram of a comparator circuit according to another embodiment of the invention. The comparator circuit 500B is a one-stage comparator and may comprise a first circuit 511, a second circuit 522, a control circuit comprising circuit subunits 531, 532 and 533 and a supplementary circuit 540. The first circuit and the second circuit have symmetric structure. That is, the structure of the first circuit and the structure of the second circuit are symmetrical with each other.

FIG. 5A and FIG. 5B show basically the same circuit. Therefore, it should be understood that in the embodiments, the components of the first circuit, the second circuit and the input circuits of a comparator circuit may be flexibly designed. The comparator circuits 500A and 500B may be reset based on the same manner. Therefore, discussion of the reset operation of the comparator circuit 500B will be omitted for brevity.

According to an embodiment of the invention, the comparator circuit 500A may receive a reset control signal CK_COMP and perform the reset operation in the reset state in response to the reset control signal CK_COMP.

The intermediate terminals to be reset may be flexibly selected. For example, the intermediate terminals may be the terminals X and Y. For another example, the intermediate terminals may also be, or may further comprise, terminals P and Q. In yet another example, the intermediate terminals may also be, or may further comprise, terminals R and S.

Taking the intermediate terminals X and Y as an example, when the reset control signal CK_COMP goes low, the comparator circuit 500A works in the reset state and the reset voltages VDD_VOP1 and VDD_VON1 are respectively provided to the intermediate terminals X and Y.

When the offset voltage of the comparator circuit 500A is not zero, the reset voltages VDD_VOP1 and VDD_VON1 may be pre-set to different voltage levels.

For example, when the input circuit 510 (or, the first circuit 511 of the comparator circuit 500B) has a driving capability stronger than that of the input circuit 520 (or, the second circuit 522 of the comparator circuit 500B), the reset voltage VDD_VOP1 may be set to a value lower than the reset voltage VDD_VON1.

To be more specific, the reset voltage VDD_VOP1 may be set to (VDD−Vcancel) when the reset voltage VDD_VON1 is set to VDD. As discussed above, the offset cancellation voltage Vcancel is positively related to the absolute value of the offset voltage.

Note that when the intermediate terminals are selected as the terminals R and S, the supply voltage VDD coupled to the terminals R and S may be replaced by different reset voltages based on the concept as described above.

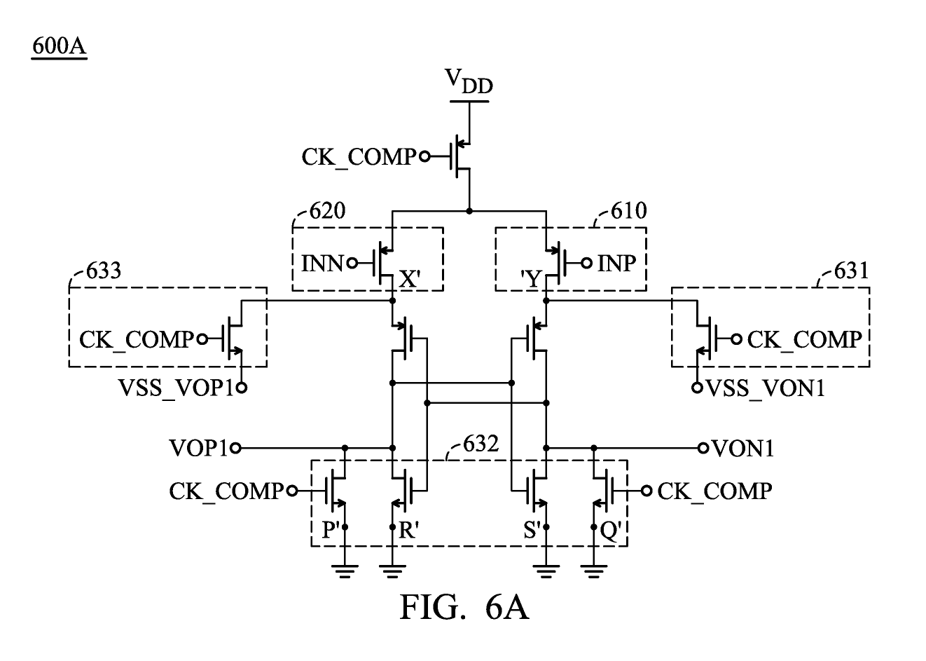

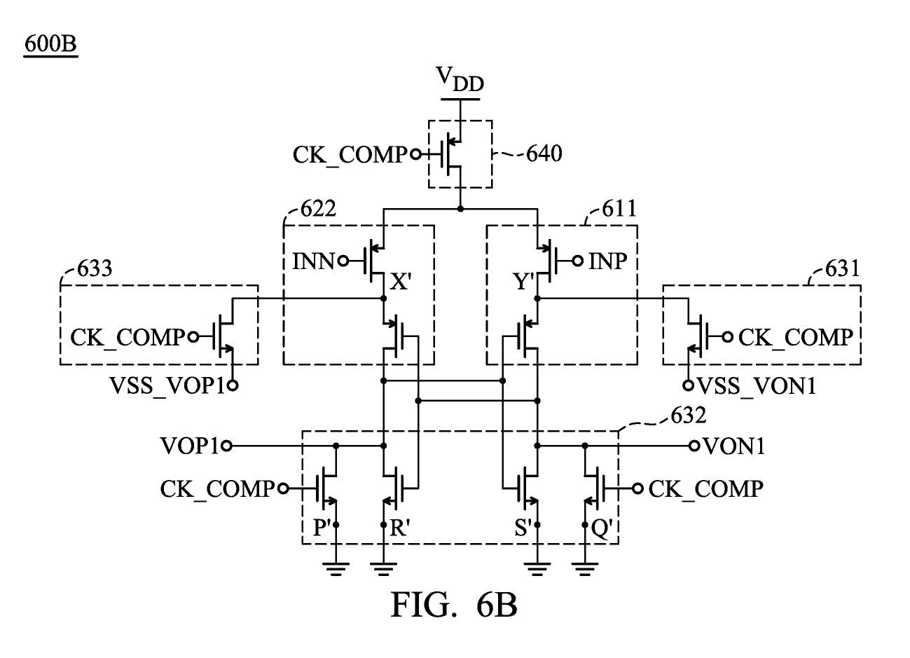

FIG. 6A is an exemplary circuit diagram of a comparator circuit according to an embodiment of the invention. The comparator circuit 600A is a one-stage comparator and may comprise input circuits 610 and 620, a control circuit comprising circuit subunits 631, 632 and 633 and an output circuit (comprising the remaining circuit elements of the comparator circuit 600A).

FIG. 6B is another exemplary circuit diagram of a comparator circuit according to another embodiment of the invention. The comparator circuit 600B is a one-stage comparator and may comprise a first circuit 611, a second circuit 622, a control circuit comprising circuit subunits 631, 632 and 633 and a supplementary circuit 640. The first circuit and the second circuit have symmetric structure. That is, the structure of the first circuit and the structure of the second circuit are symmetrical with each other.

FIG. 6A and FIG. 6B show basically the same circuit. Therefore, it should be understood that in the embodiments, the components of the first circuit, the second circuit and the input circuits of a comparator circuit may be flexibly designed. The comparator circuits 600A and 600B may be reset based on the same manner. Therefore, discussion of the reset operation of the comparator circuit 600B will be omitted for brevity.

According to an embodiment of the invention, the comparator circuit 600A may receive a reset control signal CK_COMP and perform the reset operation in the reset state in response to the reset control signal CK_COMP.

The intermediate terminals to be reset may be flexibly selected. For example, the intermediate terminals may be the terminals X′ and Y′. For another example, the intermediate terminals may also be, or may further comprise, terminals P′ and Q′. In yet another example, the intermediate terminals may also be, or may further comprise, terminals R′ and S′.

Taking the intermediate terminals X′ and Y′ as an example, when the reset control signal CK_COMP goes high, the comparator circuit 600A works in the reset state and the reset voltages VSS_OP1 and VSS_VON1 are respectively provided to the intermediate terminals X′ and Y′.

When the offset voltage of the comparator circuit 600A is not zero, the reset voltages VSS_VOP1 and VSS_VON1 may be pre-set to different voltage levels.

For example, when the input circuit 610 (or, the first circuit 611 of the comparator circuit 600B) has a driving capability stronger than that of the input circuit 620 (or, the second circuit 622 of the comparator circuit 600B), the reset voltage VSS_VOP1 may be set to a value greater than the reset voltage VSS_VON1.

To be more specific, the reset voltage VSS VOP1 may be set to (VSS+Vcancel) when the reset voltage VSS_VON1 is set to VSS. As discussed above, the offset cancellation voltage Vcancel is positively related to the absolute value of the offset voltage.

Note that when the intermediate terminals are selected as the terminals R′ and S′, and the ground voltage VSS coupled to the terminals R′ and S′ may be replaced by different reset voltages based on the concept as described above.

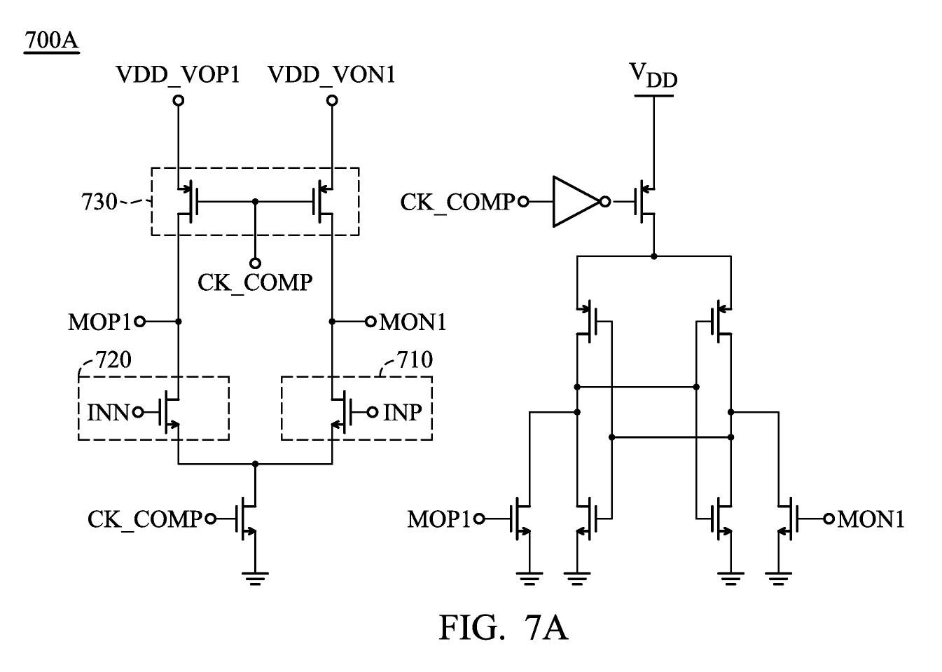

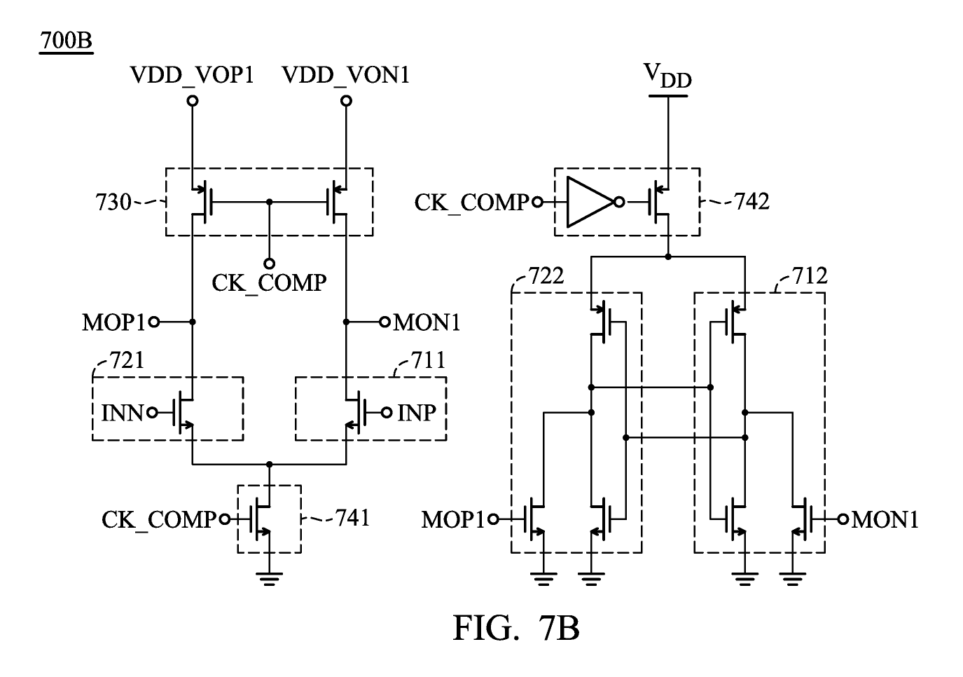

FIG. 7A is an exemplary circuit diagram of a comparator circuit according to an embodiment of the invention. The comparator circuit 700A is a two-stage comparator and may comprise input circuits 710 and 720, a control circuit 730 and an output circuit (comprising the remaining circuit elements of the comparator circuit 700A).

FIG. 7B is another exemplary circuit diagram of a comparator circuit according to another embodiment of the invention. The comparator circuit 700B is a two-stage comparator and may comprise a first circuit comprising circuit subunits 711 and 712, a second circuit comprising circuit subunits 721 and 722, a control circuit 730 and a supplementary circuit comprising circuit subunits 741 and 742. The first circuit and the second circuit have symmetric structure. That is, the structure of the first circuit and the structure of the second circuit are symmetrical with each other.

FIG. 7A and FIG. 7B show basically the same circuit. Therefore, it should be understood that in the embodiments, the components of the first circuit, the second circuit and the input circuits of a comparator circuit may be flexibly designed. The comparator circuits 700A and 700B may be reset based on the same manner. Therefore, discussion of the reset operation of the comparator circuit 700B will be omitted for brevity.

According to an embodiment of the invention, the comparator circuit 700A may receive a reset control signal CK_COMP and perform the reset operation in the reset state in response to the reset control signal CK_COMP.

The intermediate terminals to be reset may be flexibly selected. For example, the intermediate terminals may be the terminals MOP1 and MON1. When the reset control signal CK_COMP goes low, the comparator circuit 700A works in the reset state and the reset voltages VDD_VOP1 and VDD_VON1 are respectively provided to the intermediate terminals MOP1 and MON1.

When the offset voltage of the comparator circuit 700A is not zero, the reset voltages VDD_VOP1 and VDD_VON1 may be pre-set to different voltage levels.

For example, when the input circuit 710 (or, the first circuit of the comparator circuit 700B) has a driving capability stronger than that of the input circuit 720 (or, the second circuit of the comparator circuit 700B), the reset voltage VDD_VOP1 may be set to a value lower than the reset voltage VDD_VON1.

To be more specific, the reset voltage VDD_VOP1 may be set to (VDD−Vcancel) when the reset voltage VDD₁₃ VON1 is set to VDD. As discussed above, the offset cancellation voltage Vcancel is positively related to the absolute value of the offset voltage.

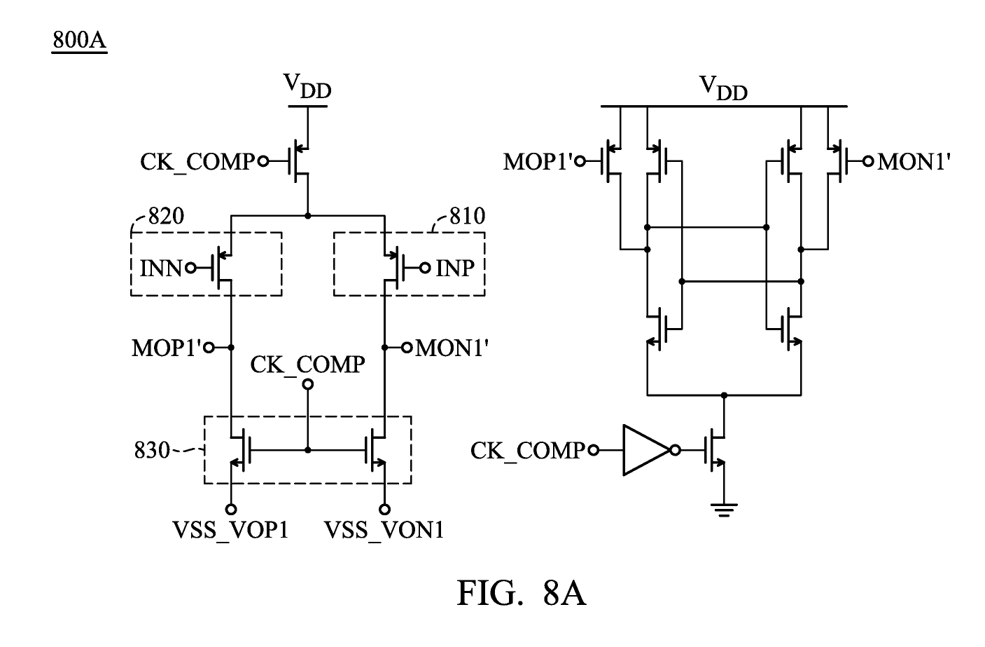

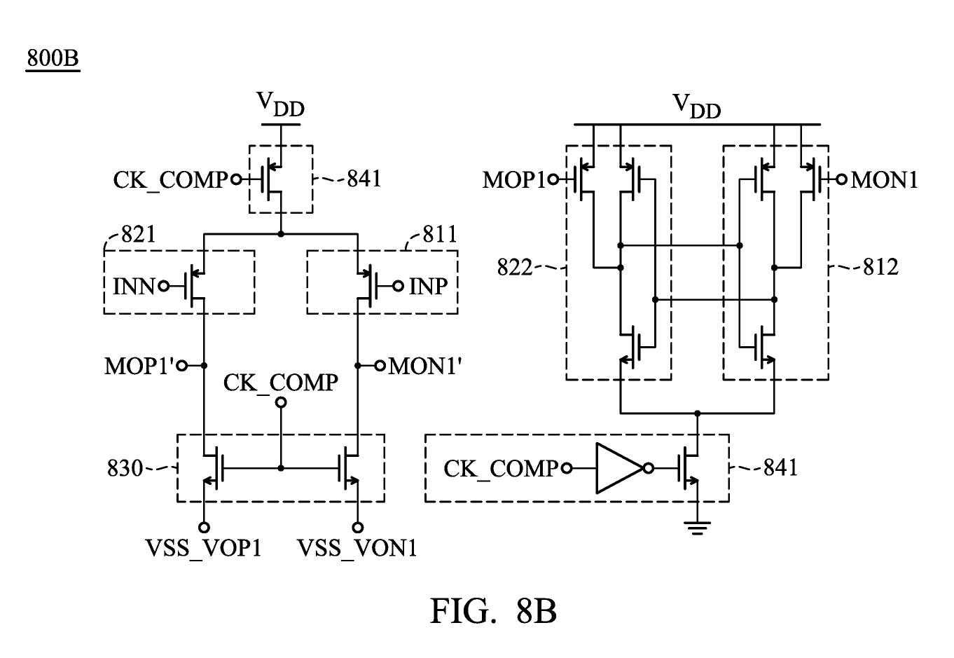

FIG. 8A is an exemplary circuit diagram of a comparator circuit according to an embodiment of the invention. The comparator circuit 800A is a two-stage comparator and may comprise input circuits 810 and 820, a control circuit 830 and an output circuit (comprising the remaining circuit elements of the comparator circuit 800A).

FIG. 8B is another exemplary circuit diagram of a comparator circuit according to another embodiment of the invention. The comparator circuit 800B is a two-stage comparator and may comprise a first circuit comprising the circuit subunits 811 and 812, a second circuit comprising the circuit subunits 821 and 822, a control circuit 830 and a supplementary circuit comprising circuit subunits 841 and 842. The first circuit and the second circuit have symmetric structure. That is, the structure of the first circuit and the structure of the second circuit are symmetrical with each other.

FIG. 8A and FIG. 8B show basically the same circuit. Therefore, it should be understood that in the embodiments, the components of the first circuit, the second circuit and the input circuits of a comparator circuit may be flexibly designed. The comparator circuits 800A and 800B may be reset based on the same manner. Therefore, discussion of the reset operation of the comparator circuit 800B will be omitted for brevity.

According to an embodiment of the invention, the comparator circuit 800A may receive a reset control signal CK_COMP and perform the reset operation in the reset state in response to the reset control signal CK_COMP.

The intermediate terminals to be reset may be flexibly selected. For example, the intermediate terminals may be the terminals MOP1′ and MON1′. When the reset control signal CK_COMP goes high, the comparator circuit 700A works in the reset state and the reset voltages VSS_VOP1 and VSS_VON1 are respectively provided to the intermediate terminals MOP1′ and MON1′.

When the offset voltage of the comparator circuit 800A is not zero, the reset voltages VSS_VOP1 and VSS_VON1 may be pre-set to different voltage levels.

For example, when the input circuit 810 (or, the first circuit of the comparator circuit 800B) has a driving capability stronger than that of the input circuit 820 (or, the second circuit of the comparator circuit 800B), the reset voltage VSS_VOP1 may be set to a value greater than the reset voltage VSS_VON1.

To be more specific, the reset voltage VSS_VOP1 may be set to (VSS+Vcancel) when the reset voltage VSS_VON1 is set to VSS. As discussed above, the offset cancellation voltage Vcancel is positively related to the absolute value of the offset voltage.

In the embodiments discussed above, after the reset operation illustrated above, the offset voltage of a comparator circuit can be compensated for, such that the transition voltage of the comparator circuit can be calibrated to 0V, which is an ideal value. When the transition voltage of the comparator circuit is 0V, the output of the comparator circuit (that is, the comparison result) is undistinguishable (for example, the percentage for the comparator circuit to output 1 is about 50% and the percentage for the comparator circuit to output 0 is also about 50% after several repetitions of the experiment) when the two input signals have the same voltage.

Note that the concept of the reset operation as illustrated above can be applied to any type of comparator circuit. Therefore, the comparator circuit should not be limited to the embodiments as illustrated above.

Use of ordinal terms such as “first”, “second”, etc., in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements.

While the invention has been described by way of example and in terms of preferred embodiment, it is to be understood that the invention is not limited thereto. Those who are skilled in this technology can still make various alterations and modifications without departing from the scope and spirit of this invention. Therefore, the scope of the present invention shall be defined and protected by the following claims and their equivalents.

What is claimed is:

1. A comparator circuit, having an offset voltage, comprising:
a first input circuit, comprising a first input terminal receiving a first input signal;
a second input circuit, comprising a second input terminal receiving a second input signal; and
a control circuit, coupled to a first intermediate terminal and a second intermediate terminal and resetting a voltage at the first intermediate terminal and a voltage at the second intermediate terminal according to an offset cancellation voltage,
wherein the first intermediate terminal is coupled between the first input terminal and a first output terminal of the comparator circuit, the second intermediate terminal is coupled between the second input terminal and a second output terminal of the comparator circuit, and the first intermediate terminal and the second intermediate terminal are symmetric terminals in the comparator circuit.

2. The comparator circuit as claimed in claim 1, wherein when the offset voltage is not zero, the voltage at the first intermediate terminal and the voltage at the second intermediate terminal are reset to different voltage levels.

3. The comparator circuit as claimed in claim 1, wherein the absolute value of the offset cancellation voltage increases as an absolute value of the offset voltage increases.

4. The comparator circuit as claimed in claim 1, wherein the control circuit provides a first reset voltage to the first intermediate terminal and provides a second reset voltage to the second intermediate terminal, and wherein a difference between the first reset voltage and the second reset voltage is the offset cancellation voltage.

5. The comparator circuit as claimed in claim 1, wherein when the first input circuit has a driving capability stronger than that of the second input circuit, the control circuit provides a reset voltage which is lower than a supply voltage to the second intermediate terminal when the voltage at the first intermediate terminal is reset to the supply voltage.

6. The comparator circuit as claimed in claim 1, wherein when the first input circuit has a driving capability stronger than that of the second input circuit, the control circuit provides a reset voltage which is greater than a ground voltage to the second intermediate terminal when the voltage at the first intermediate terminal is reset to the ground voltage.

7. The comparator circuit as claimed in claim 1, wherein the
control circuit resets the voltage at the first intermediate terminal and the voltage at the second intermediate terminal in a reset state of the comparator circuit.

8. A comparator circuit, having an offset voltage, comprising:
a first circuit, comprising a first input terminal receiving a first input signal and a first output terminal;
a second circuit, comprising a second input terminal receiving a second input signal and a second output terminal, wherein the first circuit and the second circuit are symmetric in structure; and
a control circuit, coupled to a first intermediate terminal and a second intermediate terminal and resetting a voltage at the first intermediate terminal and a voltage at the second intermediate terminal according to an offset cancellation voltage,
wherein the first intermediate terminal is located on a path from the first input terminal to the first output terminal, the second intermediate terminal is located on a path from the second input terminal to the second output terminal, and the first intermediate terminal and the second intermediate terminal are symmetric terminals in the comparator circuit.

9. The comparator circuit as claimed in claim 8, wherein when the offset voltage is not zero, the voltage at the first intermediate terminal and the voltage at the second intermediate terminal are reset to different voltage levels.

10. The comparator circuit as claimed in claim 8, wherein the offset cancellation voltage increases as an absolute value of the offset voltage increases.

11. The comparator circuit as claimed in claim 8, wherein the control circuit provides a first reset voltage to the first intermediate terminal and provides a second reset voltage to the second intermediate terminal, and wherein a difference between the first reset voltage and the second reset voltage is the offset cancellation voltage.

12. The comparator circuit as claimed in claim 8, wherein when the first circuit has a driving capability stronger than that of the second circuit, the control circuit provides a reset voltage which is lower than a supply voltage to the second intermediate terminal when the voltage at the first intermediate terminal is reset to the supply voltage.

13. The comparator circuit as claimed in claim 8, wherein when the first circuit has a driving capability stronger than that of the second circuit, the control circuit provides a reset voltage which is greater than a ground voltage to the second intermediate terminal when the voltage at the first intermediate terminal is reset to the ground voltage.

14. The comparator circuit as claimed in claim 8, wherein the control circuit resets the voltage at the first intermediate terminal and the voltage at the second intermediate terminal in a reset state of the comparator circuit.
